(19) United States
(12) Patent Application Publication
(10) Pub. No.: US 2025/0047219 A1
(43) Pub. Date: Feb. 6, 2025

(54) PIEZO/BIMETAL ELECTRICITY SOURCE

(71) Applicant: DRYAD NETWORKS GMBH, Eberswalde (DE)

(72) Inventors: Carsten BRINKSCHULTE, Berlin (DE); Marco BÖNIG, Dortmund (DE)

(73) Assignee: DRYAD NETWORKS GMBH, Eberswalde (DE)

(21) Appl. No.: 18/719,862

(22) PCT Filed: Dec. 14, 2022
(86) PCT No.: PCT/EP2022/085952

§ 371 Date: Jun. 14, 2024

(30) Foreign Application Priority Data
Dec. 15, 2021 (DE) 10 2021 133 220.6

(51) Int. Cl. H02N 2/18; H02N 1/08; H10N 30/30

(52) U.S. Cl. CPC H02N 2/181; H02N 1/08; H10N 30/306

(57) ABSTRACT

The invention relates to a device for generating electrical energy from temperature fluctuations having a first bimetal lamella coupled to an energy conversion device and a second bimetal lamella coupled to an energy conversion device, the energy conversion device being connected to a battery/energy storage device, the first bimetal lamella being different from the second bimetal lamella, and an energy conversion device comprising a bimetal lamella, a first piezoelectric element, the bimetal lamella being coupled to the first piezoelectric element, the energy conversion device having a second piezoelectric element, the second piezoelectric element being coupled to the bimetal lamella. The invention also relates to using a device for generating electrical energy from temperature fluctuations, the device for generating electrical energy from temperature fluctuations having a first and a second bimetal lamella, the two bimetal lamellas each having an upper and a lower transition temperature, the upper transition temperatures of the two bimetal lamellas and/or the lower transition temperatures of the two bimetal lamellas being different.

The invention relates to a device for generating electrical energy from temperature fluctuations having a first bimetal lamella coupled to an energy conversion device and a second bimetal lamella coupled to an energy conversion device, the energy conversion device being connected to a battery/energy storage device, the first bimetal lamella being different from the second bimetal lamella, and an energy conversion device comprising a bimetal lamella, a first piezoelectric element, the bimetal lamella being coupled to the first piezoelectric element, the energy conversion device having a second piezoelectric element, the second piezoelectric element being coupled to the bimetal lamella. The invention also relates to using a device for generating electrical energy from temperature fluctuations, the device for generating electrical energy from temperature fluctuations having a first and a second bimetal lamella, the two bimetal lamellas each having an upper and a lower transition temperature, the upper transition temperatures of the two bimetal lamellas and/or the lower transition temperatures of the two bimetal lamellas being different.

The invention further relates to a method for generating electrical energy from temperature fluctuations having the method steps of absorbing or releasing thermal energy into a first bimetal lamella of a device for generating electrical energy from temperature fluctuations, deforming the first bimetal lamella as a result of the temperature fluctuation, generating a first piezoelectric effect through the deformation of the first bimetal lamella, absorbing or releasing thermal energy into a second bimetal lamella of a device for generating electrical energy from temperature fluctuations, deforming the second bimetal lamella as a result of the temperature fluctuation, generating a second piezoelectric effect through the deformation of the first bimetal lamella, the first bimetal lamella being different from the second bimetal lamella.

### BACKGROUND

Devices and sensors that are used, for example, to monitor systems and areas often require only a small amount of energy, either because they are not continuously operated or because the sensors themselves are designed to be very energy efficient. Examples include smoke detectors. For example, batteries—also rechargeable ones—are used to supply energy. However, it may be reasonable to avoid batteries because testing and replacing them is too complex if the loads are mounted inaccessibly or are difficult to reach.

One possibility is to generate electrical energy using piezoelectric materials that generate electrical voltage when force is applied through pressure or vibration. A prototype and the operating principle of such a device is described in the document “Thermal Energy Harvesting Using Pyroelectric and Piezoelectric Effect” (Miwon Kang and Eric M. Yeatman 2016 J. Phys.: Conf. Ser. 773 012073). However, the output power of the device is limited, as is the temperature range in which the device is operable.

Thus, the object of the invention is to provide an improved device for generating electrical energy from temperature fluctuations that has an increased efficiency and increased power output. It is also an object of the present invention to provide an improved method for generating electrical energy from temperature fluctuations, through which increased efficiency and increased power output may be achieved.

The object is achieved by means of the device for generating electrical energy from temperature fluctuations according to claim 1. Advantageous embodiments of the invention are set out in the dependent claims.

The device according to the invention for generating electrical energy from temperature fluctuations has a first bimetal lamella and a second bimetal lamella. The first and second bimetal lamellas are coupled to an energy conversion device. The energy conversion device itself is connected to an energy storage device for storing electrical energy, for example, a battery or a capacitor. According to the invention, the first bimetal lamella and the second bimetal lamella are designed differently from one another. The two bimetal lamellas differ in particular in their coefficients of thermal expansion. As a result, the deformation of the two bimetal lamellas is different at a given temperature, resulting in a different power output at a given temperature. Therefore, the amount of electrical energy generated by an energy conversion device coupled to a bimetal depends on the temperature and thus also on the time at which the respective temperature is reached. The output of electrical energy output per unit of time by the device according to the invention may therefore advantageously be adjusted in such a way that the electrical power required for the use of the device is output within a defined temperature range.

A bimetal lamella has two layers of different metals lying one above the other. The two layers are firmly bonded to one another or connected by a form-fitting material. Due to the different coefficients of thermal expansion of the metals used, one of the layers expands more than the other, causing the bimetal lamella to bend when the temperature changes. The energy conversion device is suitable and intended to convert a deformation of the bimetal lamellas into electrical energy, e.g., a piezoelectric element. The output power is essentially determined by the mechanical deformation of the bending structure. The greater the deflection, the greater the charge and power generated.

In a further embodiment of the invention, a respective portion of the bimetal lamellas is arranged to be freely movable, while another respective part of the bimetal lamellas is supported. Due to the different expansion coefficients of the two metals forming a bimetal lamella, the bimetal lamellas deform when both heated and cooled. When heated, the deformation transitions, e.g., from a substantially flat shape to a curved shape.

In a further development of the invention, one end of the bimetal lamella is supported. The non-supported end of a bimetal lamella translates from the rest position of the bimetal lamella due to the deformation under the influence of temperature.

In a further embodiment of the invention, the bimetal lamella is supported at two locations and is designed to be movable between these locations. Preferably, the bimetal lamella is supported at the ends. The deformation due to thermal influence is such that the bimetal lamella enters at least two different resting states depending on the temperature. These deformations generate electrical charges through tension or pressure in the energy conversion device, which may be measured as electrical voltage at the electrodes of the energy conversion device.

In a further embodiment of the invention, the bimetal lamella is designed to be movable between its ends in a direction perpendicular to the interface between the metallic layers of the bimetal lamellas. The movement due to thermal influence is perpendicular to the layers of the bimetal lamella such that the bimetal lamella enters at least two different resting states depending on the temperature.

In a further embodiment of the invention, the energy conversion device is a piezoelectric element and/or an electret-based capacitive converter. This deformation of the bimetal lamella due to thermal influence is converted into electrical energy by a piezoelectric material, which is deformed or shaken when the bimetallic lamella bends. A piezoelectric element generates electrical voltage when force is applied through pressure or vibration, i.e., kinetic energy present in the environment is used.

An electret is an electrically insulating material that contains quasi-permanently stored electrical charges or quasi-permanently aligned electrical dipoles and thus creates a quasi-permanent electric field in its surrounding environment or interior. Technically, electrets are sometimes used in very large quantities, e.g., as membranes in sound transducers (electret microphones or headphones).

In an advantageous embodiment of the invention, the first bimetal lamella has a lower transition temperature and an upper transition temperature, the lower and/or the upper transition temperature of the first bimetal lamella being different from the lower and/or the upper transition temperature of the second bimetal lamella.

A transition temperature marks the transition from one resting state to another resting state of the respective bimetal lamella. The lower transition temperature is at a lower temperature than the upper transition temperature. At the lower transition temperature, a transition from a first rest state to a second rest state occurs at a decreasing temperature, i.e., from temperatures greater than the lower transition temperature to temperatures less than the lower transition temperature. At the upper transition temperature, a transition from the first rest state to the second rest state occurs with increasing temperatures, i.e., with a transition from temperatures lower than the upper transition temperature to temperatures greater than the upper transition temperature. Upon transition from the first rest state to the second rest state and from the second rest state to the first rest state, respectively, a large amount of electrical power is generated.

In particular, the two bimetal lamellas have different lower and upper transition temperatures. Therefore, the two bimetal lamellas have different operating temperature ranges. Thus, when using a piezoelectric element as an energy conversion device, the first and second bimetal lamellas generate an amount of electrical energy at different temperatures.

In a further embodiment of the invention, the first bimetal lamella has a first lower transition temperature and a first upper transition temperature, and the second bimetal lamella has a second lower transition temperature and a second upper transition temperature. Advantageously, the second upper transition temperature of the second bimetal lamella is between the first lower transition temperature and the first upper transition temperature of the first bimetal lamella and/or the second lower transition temperature of the second bimetal lamella is between the first lower transition temperature and the first upper transition temperature of the first bimetal lamella. That is, the two bimetal lamellas have different operating temperature ranges. Advantageously, the operating temperature ranges of the two bimetal lamellas overlap such that the overall operating temperature range of the device according to the invention is increased compared to the arrangement of only one bimetal lamella.

In a further advantageous embodiment of the invention, the device for generating electrical energy from temperature fluctuations has an array of bimetal lamellas. Using arrays of bimetal lamellas increases the operating temperature range in which the array may generate electrical energy. In areas with fluctuating temperatures, electrical energy may be generated in any temperature range. When used outdoors, energy may be generated day and night or also at different times of the year.

In a further development of the invention, the array has a plurality of bimetal lamellas. Using a plurality of bimetal lamellas in an array increases the operating temperature range in which the array may generate electrical energy. In areas with fluctuating temperatures, electrical energy may be generated in any temperature range. When used outdoors, energy may be generated day and night or also at different times of the year.

In a further embodiment of the invention, the bimetal lamellas of the array each have a temperature interval between the lower and upper transition temperatures of the respective bimetal lamella. Advantageously, the temperature intervals of the bimetal lamellas overlap one another such that they form a continuous overall temperature interval. Thus, the overall operating temperature range of the device according to the invention is increased compared to the arrangement of only one bimetal lamella.

In a further embodiment of the invention, the device for generating electrical energy from temperature fluctuations has a maximum operating temperature range. The maximum operating temperature range is defined by the respective operating temperature ranges of the bimetal lamellas arranged in the device.

In a further embodiment of the invention, the temperature interval between the lowest lower transition temperature and the highest upper transition temperature of the device for generating electrical energy from temperature fluctuations form the maximum operating temperature range of the device. Therefore, the lowest lower transition temperature of a bimetal lamella and the highest upper transition temperature of a bimetal lamella of the device for generating electrical energy from temperature fluctuations define the extremes of the operating temperature range of the device. When arranging a plurality of different bimetal lamellas having different lower and upper transition temperatures, respectively, the overall operating temperature range of the device according to the invention is increased compared to the arrangement of only one bimetal lamella.

In a further development of the invention, the device for generating electrical energy from temperature fluctuations has a minimum operating temperature range. The minimum operating temperature range defines the smallest operating temperature range of the device.

In a further embodiment of the invention, the smallest temperature interval of a bimetal lamella of the array of the device for generating electrical energy from temperature fluctuations forms the minimum operating temperature range. Each bimetal lamella of the array has a lower transition temperature and an upper transition temperature. The temperature interval between these transition temperatures is the operating temperature range of the respective bimetal lamella. The smallest temperature interval of a bimetal lamella of the array defines the minimum operating temperature range of the device.

In a further embodiment of the invention, the first and/or second bimetal lamellas are coupled to the same energy conversion device. Therefore, the device according to the invention only requires one energy conversion device and thus is inexpensive to produce while having a simple structure.

In a further embodiment of the invention, the first and/or second bimetal lamellas are coupled to the same energy conversion device. The energy conversion device may then be adapted to the corresponding deformations of a bimetal lamella such that maximum electrical energy yield and maximum electrical power may be achieved.

In a further development of the invention, the first and/or second bimetal lamellas are permanently coupled to the energy conversion device. Therefore, a bimetal lamella forms a component with an energy conversion device. Such a component has, e.g., piezoelectric ceramic plates or films, which are embedded in a polymer including contacting. As a result, the inherently brittle ceramic is mechanically biased while being electrically insulated. Mechanically biasing expands the limits of the resilience of the ceramic, allowing it to be applied also to curved surfaces. At the same time, the compact structure including the insulation simplifies handling for the user; there is even the possibility of embedding the surface converter in a composite material. Ideally, such components have a symmetrical design, i.e., when the bimetal lamella is bent, equal amounts of charge with opposite signs are generated on both electrode surfaces.

The object is also achieved by using an energy conversion device. Advantageous embodiments are set out in the dependent claim 18.

The energy conversion device according to the invention has a bimetal lamella and a first piezoelectric element coupled to the bimetal lamella. According to the invention, the energy conversion device has a second piezoelectric element also coupled to the bimetal lamella. The two bimetal lamellas differ in particular in their coefficients of thermal expansion. As a result, the deformation of the two bimetal lamellas is different at a given temperature, resulting in a power output at different temperatures. Therefore, the amount of electrical energy that the device according to the invention outputs per unit of time may advantageously be adjusted such that the electrical power required for the use of the device is output within a defined temperature range.

In a further development of the invention, the bimetal lamella is permanently coupled to the first piezoelectric element. Therefore, a bimetal lamella forms a component with an energy conversion device. Such a component has, e.g., piezoelectric ceramic plates or films, which are embedded in a polymer including contacting. As a result, the inherently brittle ceramic is mechanically biased while being electrically insulated. Mechanically biasing expands the limits of the resilience of the ceramic, allowing it to be applied also to curved surfaces. At the same time, the compact structure including the insulation simplifies handling for the user; there is even the possibility of embedding the surface converter in a composite material. Ideally, such components have a symmetrical design, i.e., when the bimetal lamella is bent, equal amounts of charge with opposite signs are generated on both electrode surfaces.

The object is further achieved through the method according to the invention for generating electrical energy from temperature fluctuations. Advantageous embodiments of the invention are set out in the dependent claims 20 to 22.

The method according to the invention for generating electrical energy from temperature fluctuations has six method steps. In the first method step, a first bimetal lamella of a device for generating electrical energy absorbs thermal energy from temperature fluctuations. In the second method step, the thermal energy is converted into a deformation of the first bimetal lamella. In the third method step, a first piezoelectric effect is generated by the deformation of the first bimetal lamella. In the fourth method step, a second bimetal lamella of a device for generating electrical energy absorbs thermal energy from temperature fluctuations. In the fifth method step, the thermal energy is converted into a deformation of the second bimetal lamella. In the sixth method step, a second piezoelectric effect is generated by the deformation of the second bimetal lamella.

According to the invention, the first bimetal lamella is different from the second bimetal lamella. A bimetal lamella has two layers of different metals lying one above the other. The two layers are firmly bonded to one another or connected by a form-fitting material. Due to the different coefficients of thermal expansion of the metals used, one of the layers expands more than the other, causing the bimetal lamella to bend when the temperature changes. The energy conversion device is suitable and intended to convert a deformation of the bimetal lamellas into electrical energy, e.g., a piezoelectric element. The output power is essentially determined by the mechanical deformation of the bending structure. The greater the deflection, the greater the charge and power generated.

According to the invention, the first bimetal lamella and the second bimetal lamella are designed differently from one another. The two bimetal lamellas differ in particular in their coefficients of thermal expansion. As a result, the deformation of the two bimetal lamellas is different at a given temperature, resulting in a different power output at a given temperature. Therefore, the amount of electrical energy that the device according to the invention outputs per unit of time may advantageously be adjusted such that the electrical power required for the use of the device is output within a defined temperature range.

In a further embodiment of the invention, the first bimetal lamella has a first lower and a first upper transition temperature. Similarly, the second bimetal lamella has a second lower and a second upper transition temperature. A transition temperature marks the transition from one resting state to another resting state of the respective bimetal lamella. The lower transition temperature is at a lower temperature than the upper transition temperature.

At the lower transition temperature, a transition from a first rest state to a second rest state occurs at a decreasing temperature, i.e., from temperatures greater than the lower transition temperature to temperatures less than the lower transition temperature. At the upper transition temperature, a transition from the first rest state to the second rest state occurs with increasing temperatures, i.e., with a transition from temperatures lower than the upper transition temperature to temperatures greater than the upper transition temperature. Upon transition from the first rest state to the second rest state and from the second rest state to the first rest state, respectively, a large amount of electrical power is generated.

Advantageously, the first lower transition temperature of the first bimetal lamella is different from the second lower transition temperature of the second bimetal lamella, similarly, the first upper transition temperature of the first bimetal lamella is different from the second upper transition temperature of the second bimetal lamella.

Therefore, the two bimetal lamellas have different operating temperature ranges where they may generate energy in conjunction with an energy conversion device. Thus, when using a piezoelectric element as an energy conversion device, the first and second bimetal lamellas generate an amount of electrical energy at different temperatures. In a further embodiment of the invention, the first bimetal lamella has a first lower transition temperature and a first upper transition temperature, and the second bimetal lamella has a second lower transition temperature and a second upper transition temperature. Advantageously, the second upper transition temperature of the second bimetal lamella is between the first lower transition temperature and the first upper transition temperature of the first bimetal lamella and/or the second lower transition temperature of the second bimetal lamella is between the first lower transition temperature and the first upper transition temperature of the first bimetal lamella. That is, the two bimetal lamellas have different operating temperature ranges. Advantageously, the operating temperature ranges of the two bimetal lamellas overlap such that the overall operating temperature range of the device according to the invention is increased compared to the arrangement of only one bimetal lamella.

In a further development of the invention, the first piezoelectric effect is generated at a first piezoelectric temperature, and the second piezoelectric effect is generated at a second piezoelectric temperature. The first piezoelectric temperature is different from the second piezoelectric temperature. Thus, the method allows for generating electrical energy at at least two different temperatures.

In a particularly advantageous embodiment of the invention, with temperature fluctuations across a temperature interval, a plurality of bimetal lamellas will be deformed at different temperatures as a result of the absorption or release of thermal energy. Using a plurality of bimetal lamellas increases the electrical energy generated per unit of time, i.e., the device according to the invention generates a higher power than the arrangement of only one bimetal lamella. At the same time, the temperature range where electrical energy may be generated is increased.

The object is also achieved by using a device for generating electrical energy from temperature fluctuations. Further advantageous embodiments of the invention are set forth in the dependent claims 24 to 26.

The device for generating electrical energy from temperature fluctuations is used according to the invention in that the device for generating electrical energy from temperature fluctuations has a first and a second bimetal lamella. The two bimetal lamellas each have a lower and an upper transition temperature.

In particular, the lower transition temperatures and/or the upper transition temperatures of the two bimetal lamellas are different from one another. Therefore, the two bimetal lamellas have different operating temperature ranges. Thus, when using a piezoelectric element as an energy conversion device, the first and second bimetal lamellas generate an amount of electrical energy at different temperatures.

In a further embodiment of the invention, the first bimetal lamella has a first lower transition temperature and a first upper transition temperature, and the second bimetal lamella has a second lower transition temperature and a second upper transition temperature. Advantageously, the second upper transition temperature of the second bimetal lamella is between the first lower transition temperature and the first upper transition temperature of the first bimetal lamella and/or the second lower transition temperature of the second bimetal lamella is between the first lower transition temperature and the first upper transition temperature of the first bimetal lamella. That is, the two bimetal lamellas have different operating temperature ranges. Advantageously, the operating temperature ranges of the two bimetal lamellas overlap such that the overall operating temperature range of the device according to the invention is increased compared to the arrangement of only one bimetal lamella.

In a further embodiment of the invention, the device for generating electrical energy from temperature fluctuations has an array of bimetal lamellas. The electrical energy generated by the device for generating electrical energy from temperature fluctuations is used as an energy supply in a network having off-grid components. Examples include a network for monitoring an area, e.g., a forest fire monitoring system. Other areas of interest for energy harvesting include data monitoring and transmission in heating and air conditioning technology, without the corresponding sensors having to be wired or equipped with batteries.

In a further development of the invention, the array has an array temperature interval where the device for generating electrical energy from temperature fluctuations is suitable for converting thermal energy into electrical energy. The device for generating electrical energy from temperature fluctuations is used in an environment having temperature fluctuations with a minimum and/or maximum temperature outside the array temperature interval.

In a further embodiment of the invention, the time intervals where the temperature fluctuations in the environment are outside the array temperature interval are greater than 24 hours, preferably 7 days and particularly preferably 28 days.

Exemplary embodiments of the device for generating electrical energy from temperature fluctuations according to the invention and the method for generating electrical energy from temperature fluctuations according to the invention are shown schematically in simplified form in the drawings and are explained in more detail in the following description.

Wherein:

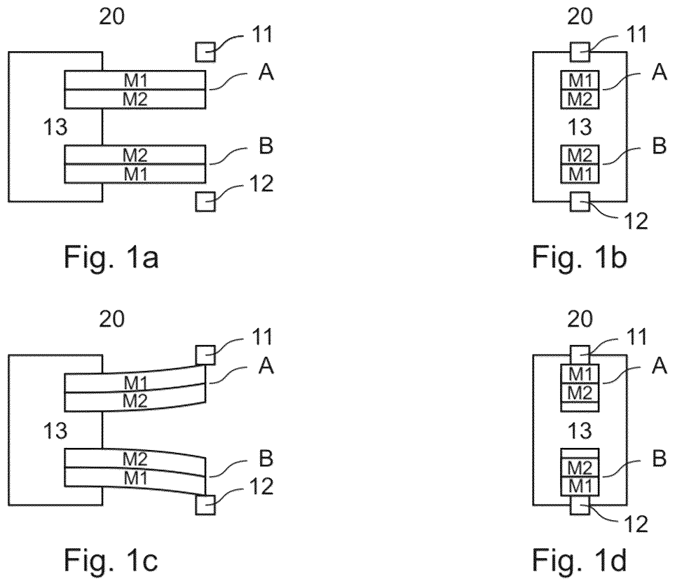

FIG. 1a is a side view of a device for generating electrical energy from temperature fluctuations according to the invention having two energy conversion devices, not actuated;

FIG. 1b is a front view of a device for generating electrical energy from temperature fluctuations according to the invention having two energy conversion devices, not actuated;

FIG. 1c is a side view of a device for generating electrical energy from temperature fluctuations according to the invention having two energy conversion devices, actuated;

FIG. 1d is a front view of a device for generating electrical energy from temperature fluctuations according to the invention having two energy conversion devices, actuated;

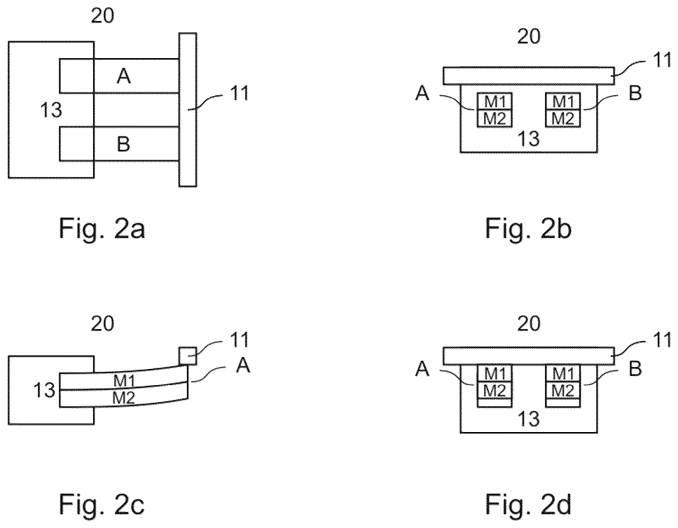

FIG. 2a is a side view of a device for generating electrical energy from temperature fluctuations according to the invention having one energy conversion device, not actuated;

FIG. 2b is a front view of a device for generating electrical energy from temperature fluctuations according to the invention having one energy conversion device, not actuated;

FIG. 2c is a side view of a device for generating electrical energy from temperature fluctuations according to the invention having one energy conversion device, actuated;

FIG. 2d is a front view of a device for generating electrical energy from temperature fluctuations according to the invention having one energy conversion device, actuated;

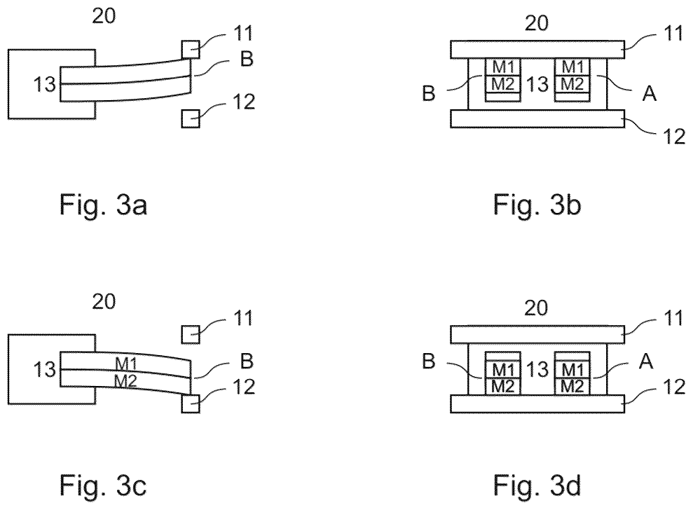

FIG. 3a is a side view of a device for generating electrical energy from temperature fluctuations according to the invention having two energy conversion devices, deflected in a first rest position;

FIG. 3b is a front view of a device for generating electrical energy from temperature fluctuations according to the invention having two energy conversion devices, deflected in a first rest position;

FIG. 3c is a side view of a device for generating electrical energy from temperature fluctuations according to the invention having two energy conversion devices, deflected in a second rest position;

FIG. 3d is a front view of a device for generating electrical energy from temperature fluctuations according to the invention having two energy conversion devices, deflected in a second rest position;

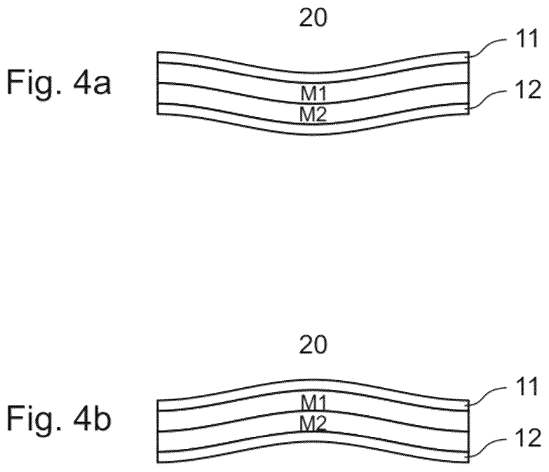

FIG. 4a is a sectional view of a device for generating electrical energy from temperature fluctuations according to the invention, deflected in the first rest position;

FIG. 4b is a sectional view of a device for generating electrical energy from temperature fluctuations according to the invention, deflected in the second rest position;

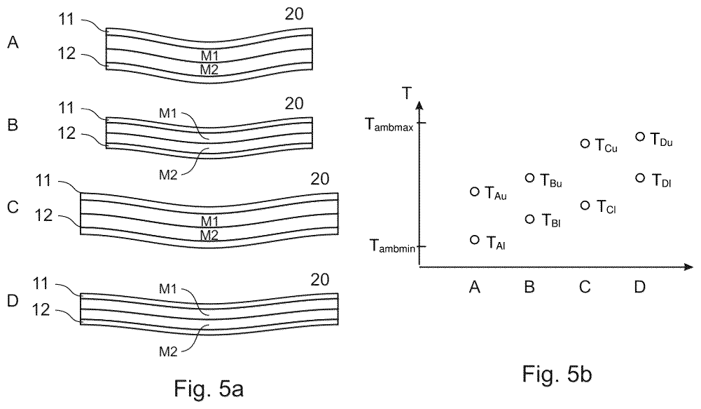

FIG. 5a is a sectional view of an array of four devices for generating electrical energy from temperature fluctuations according to the invention;

FIG. 5b illustrates the temperature intervals of the array of four devices according to the invention for generating electrical energy from temperature fluctuations according to the invention;

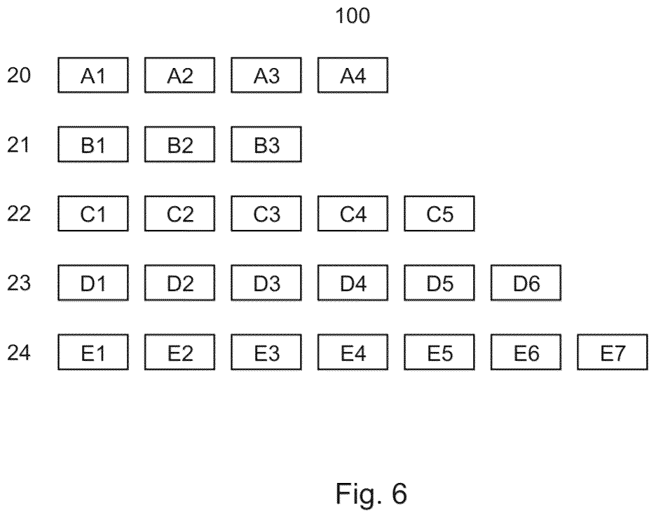

FIG. 6 is an exemplary embodiment of an application of an array of devices for generating electrical energy from temperature fluctuations according to the invention.

FIG. 1 shows an exemplary embodiment of the device 1 for generating electrical energy from temperature fluctuations according to the invention. The device 1 has a first bimetal lamella A and a second bimetal lamella B. The two bimetal lamellas A, B are formed from two layers M1, M2 of different metals or alloys having different expansion coefficients, the two layers M1, M2 being bonded to one another by rolling, welding, gluing or directly by application, e.g., by directly spraying a second material onto a first material, such that a monolithic bimetal lamella A, B is formed.

The device has the energy conversion device 20 comprising two bimetal lamellas A, B and two piezoelectric elements 11, 12. The bimetal lamellas A, B are arranged parallel to one another in an undeflected state (FIG. 1a, 1b). The two bimetal lamellas A, B are supported at one end in the support 13 such that the end opposite the supported end is freely movable in a direction perpendicular to the interfaces between the metallic layers M1, M2. The two piezoelectric elements 11, 12 are arranged near the movable ends of the bimetal lamellas A, B such that when the bimetal lamellas A, B are deflected, the piezoelectric elements 11, 12 are deformed. In a further embodiment, instead of the piezoelectric elements 11, 12, capacitive converters based on an electret may be employed. This deformation is converted into electrical energy by the energy conversion device 20, the piezoelectric elements 11, 12, which are deformed or shaken when the bimetallic lamellas A, B bend.

Advantageously, the two bimetal lamellas A, B are designed differently from one another. In particular, they differ in the temperature at which the bimetal lamellas A, B apply a maximum force on a piezoelectric element 11, 12 and generate a maximum electrical voltage. The materials for producing the bimetal lamellas A, B are selected according to the temperature range where the device 1 is to operate.

For generating electrical energy from temperature fluctuations, the first bimetal lamella A and the second bimetal lamella B simultaneously absorb thermal energy. The thermal energy is converted into a deformation of the first A and the second bimetal lamella B. In this exemplary embodiment, the free ends of the bimetal lamellas A, B are deflected in opposite directions relative to one another. The deformation is converted into electrical energy by the piezoelectric elements 11, 12. When the first bimetal lamella A contacts and applies pressure on the first piezoelectric element 11, electrical energy is generated in the first piezoelectric element 11, when the second bimetal lamella B contacts and applies pressure on the second piezoelectric element 12, electrical energy is generated in the second piezoelectric element 12 (FIG. 1c, 1d). The electrical energy generated is supplied to a load or stored in a storage device. Advantageously, the energy conversion device 20 is connected to an energy storage device, e.g., a battery or a storage capacitor. According to the invention, the two bimetal lamellas A, B are designed such that they have a different deformation at a given temperature, thereby applying a different force on the piezoelectric elements 11, 12.

A further exemplary embodiment of the device 1 according to the invention is shown in FIG. 2. In this exemplary embodiment, the device 1 also has two bimetal lamellas A, B, which are also arranged parallel to one another in the undeflected state (FIG. 2a, 2b). The two bimetal lamellas A, B are supported at one end in the support 13 such that the end opposite the supported end is freely movable in a direction perpendicular to the interfaces between the metallic layers M1, M2. The energy conversion device 20 has a piezoelectric element 11 arranged near the movable ends of the bimetal lamellas A, B such that the piezoelectric element 11 is deformed when the bimetal lamellas A, B are deflected.

When thermal energy is supplied, the thermal energy is in turn converted into a deformation of the first bimetal lamella A and the second bimetal lamella B. In this exemplary embodiment, the free ends of the bimetal lamellas A, B are deflected in the same direction. The deformation is converted into electrical energy by the piezoelectric element 11. When the first bimetal lamella A contacts and applies pressure on the piezoelectric element 11, electrical energy is generated in the first piezoelectric element 11, similarly, when the second bimetal lamella B contacts and applies pressure on the piezoelectric element 11 (FIG. 2c, 2d).

Another variant of the arrangement of the energy conversion device 20 is shown in FIG. 3. In this exemplary embodiment the device 1 also has two bimetal lamellas A, B supported at one end in the support 13 such that the end opposite to the supported end is freely movable in a direction perpendicular to the interfaces between the metallic layers M1, M2. The two piezoelectric elements 11, 12 are arranged near the movable ends of the bimetal lamellas A, B.

In this exemplary embodiment, the design and material of the bimetal lamellas A, B is selected such that, at a first temperature T1 (FIG. 3a, 3b), the bimetal lamellas A, B contact and apply pressure on the first piezoelectric element 11, thereby generating electrical energy. At a temperature T2 different from the first temperature T1 (FIG. 3c, 3d), the bimetal lamellas A, B are deformed such that they contact and apply pressure on the second piezoelectric element 12, thereby generating electrical energy.

FIG. 4 shows a sectional view of an exemplary embodiment of the structure of an energy conversion device 20. The bimetal lamella A has two metallic layers M1, M2, each of which is coated with a piezoelectric element 11, 12. As such, there is a permanent coupling between the metallic layers M1, M2 and the piezoelectric elements 11, 12. In this exemplary embodiment, the bimetal lamella A is supported at both ends such that the bimetal lamella A is movable between its ends in a direction perpendicular to the interfaces of the metallic layers M1, M2. The bimetal lamella A has two rest states depending on the temperature to which it is exposed. Due to the different expansion coefficients of the two metallic layers M1, M2, the bimetal lamella A deforms when both heated and cooled. Contrary to the previous exemplary embodiments (FIGS. 1-3), this deformation does not occur continuously, but suddenly at a transition temperature.

In the two rest states, the bimetal lamella A has a different deformation. The deformation depends on the temperature to which it is exposed, and on the original characteristics of the material, e.g., thickness or coefficient of thermal expansion. Therefore, the first piezoelectric effect of the piezoelectric elements 11, 12 is generated at a first piezo temperature, and the second piezoelectric effect is generated at a second piezoelectric temperature, in other words, in the first rest state (FIG. 4a), the energy conversion device generates a different amount of electrical energy per unit of time than in the second rest state (FIG. 4b). In addition, a large amount of electrical power is generated during the transition from the first rest state to the second rest state.

In a further embodiment, the bimetal lamella A has two transition temperatures, a first lower transition temperature and a first upper transition temperature. Each transition temperature indicates a rest state of the bimetal lamella A. In each rest state, the bimetal lamella A has a curvature or deformation, the curvatures or deformations of the rest states preferably being opposite to one another. The temperature interval between the lower and upper transition temperature defines the operating temperature range of the bimetal lamella A.

An exemplary embodiment of a device 1 according to the invention is shown in FIG. 5. The device 1 has an array 100 of four bimetal lamellas A, B, C, D, each of which forms an energy conversion device 20 (FIG. 5a). A bimetal lamella A, B, C, D each has two metallic layers M1, M2, each of which is coated with a piezoelectric element 11, 12. The bimetal lamellas A, B, C, D are supported at both ends such that the bimetal lamellas A, B, C, D are movable between their ends in a direction perpendicular to the interfaces of the metallic layers M1, M2.

Each of the four bimetal lamellas A, B, C, D has two respective transition temperatures, a lower transition temperature and an upper transition temperature (FIG. 5b): The bimetal lamella A has the lower transition temperature TAI and the upper transition temperature TAu, the bimetal lamella B has the lower transition temperature TBI and the upper transition temperature TBu, the bimetal lamella C has the lower transition temperature TCl and the upper transition temperature TCu, and the bimetal lamella D has the lower transition temperature TDI and the upper transition temperature TDu. Each bimetal lamella A, B, C, D has an operating temperature range defined by the temperature interval between their respective lower and upper transition temperatures. Advantageously, in this exemplary embodiment, the respective operating temperature ranges of the bimetal lamellas A, B, C, D overlap such that they form a continuous overall temperature interval. The overall temperature interval is defined by the lowest transition temperature (here: TAI) of all the bimetal lamellas A, B, C, D arranged in the array 100 and the highest transition temperature (here: TDu) of all the bimetal lamellas A, B, C, D arranged in the array 100. As such, the device 1 for generating electrical energy from temperature fluctuations has an overall temperature interval between the ambient temperatures Tambmin and Tambmax.

FIG. 6 shows an exemplary embodiment of a device 1 for generating electrical energy from temperature fluctuations according to the invention. In this exemplary embodiment, the device 1 has an array of five energy conversion devices 20, 21, 22, 23, 24, each of which has a different number of bimetal lamellas A, A1, A2, A3, A4, B, B1, B2, B3, C, C1, C2, C3, C4, C5, D, D1, D2, D3, D4, D5, D6, E1, E2, E3, E4, E5, E6, E7. Within an energy conversion device 20, 21, 22, 23, 24, all of the bimetal lamellas A, A1, A2, A3, A4, B, B1, B2, B3, C, C1, C2, C3, C4, C5, D, D1, D2, D3, D4, D5, D6, E1, E2, E3, E4, E5, E6, E7 have the same operating temperature ranges. The energy conversion device 20 has the bimetal lamellas A, A1, A2, A3, A4, the bimetal lamellas A, A1, A2, A3, A4 having the same lower and upper transition temperatures relative to one another. Similarly, the bimetal lamellas B, B1, B2, B3 of the energy conversion device 21 have the same lower and upper transition temperatures relative to one another, the bimetal lamellas C, C1, C2, C3, C4, C5 of the energy conversion device 22 have the same lower and upper transition temperatures relative to one another, the bimetal lamellas D, D1, D2, D3, D4, D5, D6 of the energy conversion device 23 have the same lower and upper transition temperatures relative to one another, and the bimetal lamellas E1, E2, E3, E4, E5, E6, E7 of the energy conversion device 24 have the same lower and upper transition temperatures relative to one another.

However, the energy conversion devices 20, 21, 22, 23, 24 advantageously have operating temperature ranges different from one another by having the lower and upper transition temperatures of the bimetal lamellas A, B, C, D, E1 differ from each other.

Thus, even in different temperature ranges, the device 1 generates electrical energy upon temperature fluctuations. As such, the electrical power of the device 1 may be adjusted such that the electrical power output is optimal in the temperature interval planned for the application, even if this temperature interval covers a large temperature range.

Preferably, the device 1 for generating electrical energy from temperature fluctuations is suitable for supplying energy to devices for data monitoring in environments that are difficult to access and/or dangerous to humans. In particular, off-grid components may also be supplied with energy by devices arranged in a network. Examples include wireless Zigbee networks or LoRaWAN, which have devices for collecting and transmitting measurement data. The device 1 for generating electrical energy from temperature fluctuations is used in an environment having temperature fluctuations with a minimum and/or maximum temperature outside the array temperature interval. In order for the device 1 to operate properly, the time intervals where the temperature fluctuations in the environment are outside the array temperature interval are greater than 24 hours, preferably 7 days and particularly preferably 28 days.

### LIST OF REFERENCE NUMERALS

1 Device for generating electrical energy from temperature fluctuations
11 First piezoelectric element
12 Second piezoelectric element
13 Support
20, 21, 22, 23, 24 Energy conversion device
100 Array
A, A1, A2, A3, A4 First bimetal lamella
B, B1, B2, B3 Second bimetal lamella
C, C1, C2, C3, C4, C5 Third bimetal lamella
D, D1, D2, D3, D4, D5, D6 Fourth bimetal lamella
E1, E2, E3, E4, E5, E6, E7 Fifth bimetal lamella
M1 First layer of the bimetal lamella
M2 Second layer of the bimetal lamella

1. A device (1) for generating electrical energy from temperature fluctuations having
a first bimetal lamella (A) coupled to an energy conversion device (20, 21, 22, 23, 24),
a second bimetal lamella (B) coupled to an energy conversion device (20, 21, 22, 23, 24),
wherein the energy conversion device (20, 21, 22, 23, 24) is connected to an energy storage device,
characterized in that
the first bimetal lamella (A) is different from the second bimetal lamella (B).

2. The device (1) for generating electrical energy from temperature fluctuations of claim 1,
characterized in that
a portion of the bimetal lamellas (A, B) is freely movable and another portion of the bimetal lamellas (A, B) is supported.

3. The device (1) for generating electrical energy from temperature fluctuations of claim 1,
characterized in that
one end of the bimetal lamellas (A, B) is supported.

4. The device (1) for generating electrical energy from temperature fluctuations of claim 1,
characterized in that
the bimetal lamellas (A, B) are supported in two positions and movable between these positions.

5. The device (1) for generating electrical energy from temperature fluctuations of claim 1,
characterized in that
the bimetal lamellas (A, B) are movable between their ends in a direction perpendicular to the interface between the metallic layers of the bimetal lamellas (A, B).

6. The device (1) for generating electrical energy from temperature fluctuations of claim 1,
characterized in that
the energy conversion device (20, 21, 22, 23, 24) is a piezoelectric element (11) and/or an electret-based capacitive converter.

7. The device (1) for generating electrical energy from temperature fluctuations of claim 1,
characterized in that
the first bimetal lamella (A) has a lower transition temperature and an upper transition temperature,
wherein the lower and/or the upper transition temperature of the first bimetal lamella (A) is different from the lower and/or the upper transition temperature of the second bimetal lamella (B).

8. The device (1) for generating electrical energy from temperature fluctuations of claim 1,
characterized in that
the first bimetal lamella (A) has a first lower transition temperature and a first upper transition temperature,
the second bimetal lamella (A) has a second lower transition temperature and a second upper transition temperature,
wherein the second upper transition temperature of the second bimetal lamella (B) is between the first lower transition temperature and the first upper transition temperature of the first bimetal lamella (A), and/or
wherein the second lower transition temperature of the second bimetal lamella (B) is between the first lower transition temperature and the first upper transition temperature of the first bimetal lamella (A).

9. The device (1) for generating electrical energy from temperature fluctuations of claim 1,
characterized in that
the device (1) for generating electrical energy from temperature fluctuations has an array (100) of bimetal lamellas (A, B, C, D, E1).

10. The device (1) for generating electrical energy from temperature fluctuations of claim 9,
characterized in that
the array (100) has a plurality of bimetal lamellas (A, B, C, D, E1).

11. The device (1) for generating electrical energy from temperature fluctuations of claim 9,
characterized in that
the bimetal lamellas (A, B, C, D, E1) of the array (100) each have a temperature interval between the lower and upper transition temperatures of the respective bimetal lamella (A, B, C, D, E1),
wherein the temperature intervals of the bimetal lamellas (A, B, C, D, E1) overlap one another such that they form a continuous overall temperature interval.

12. The device (1) for generating electrical energy from temperature fluctuations of claim 9,
characterized in that
the device (1) for generating electrical energy from temperature fluctuations has a maximum operating temperature range.

13. The device (1) for generating electrical energy from temperature fluctuations of claim 12,
characterized in that
the temperature interval between the lowest lower transition temperature and the highest upper transition temperature of the device (1) for generating electrical energy from temperature fluctuations form the maximum operating temperature range.

14. The device (1) for generating electrical energy from temperature fluctuations of claim 1,
characterized in that
the first (A) and/or the second bimetal lamella (B) are coupled to the same energy conversion device (20, 21, 22, 23, 24).

15. The device (1) for generating electrical energy from temperature fluctuations of claim 1,
characterized in that
the first (A) and/or the second bimetal lamella (B) are coupled to a second energy conversion device (20, 21, 22, 23, 24).

16. The device (1) for generating electrical energy from temperature fluctuations of claim 1,
characterized in that
the first (A) and/or the second bimetal lamella (B) are permanently coupled to the energy conversion device (20, 21, 22, 23, 24).

17. An energy conversion device (20, 21, 22, 23, 24), comprising
a bimetal lamella (A),
a first piezoelectric element (11),
wherein the bimetal lamella (A) is coupled to the first piezoelectric element (11),
characterized in that
the energy conversion device (20, 21, 22, 23, 24) has a second piezoelectric element (12),
wherein the second piezoelectric element (12) is coupled to the bimetal lamella (A).

18. The energy conversion device (20, 21, 22, 23, 24) of claim 17,
characterized in that
the bimetal lamella (A) is permanently coupled to the first piezoelectric element (11).

19. A method for generating electrical energy from temperature fluctuations having the method steps of
absorbing or releasing thermal energy into a first bimetal lamella (A) of a device (1) for generating electrical energy from temperature fluctuations,
deforming the first bimetal lamella (A) as a result of the temperature fluctuation,
generating a first piezoelectric effect caused by the deformation of the first bimetal lamella (A),
absorbing or releasing thermal energy into a second bimetal lamella (B) of a device (1) for generating electrical energy from temperature fluctuations,
deforming the second bimetal lamella (B) as a result of the temperature fluctuation,
generating a second piezoelectric effect caused by the deformation of the first bimetal lamella (B),
characterized in that
the first bimetal lamella (A) is different from the second bimetal lamella (B).

20. The method for generating electrical energy from temperature fluctuations of claim 19,
characterized in that
the first bimetal lamella (A) has a first lower and a first upper transition temperature, and the second bimetal lamella (A) has a second lower and a second upper transition temperature,
wherein the first lower transition temperature of the first bimetal lamella (A) is different from the second lower transition temperature of the second bimetal lamella (B), and/or
wherein the first upper transition temperature of the first bimetal lamella (A) is different from the second upper transition temperature of the second bimetal lamella (B).

21. The method for generating electrical energy from temperature fluctuations of claim 19,
characterized in that
the first piezoelectric effect is generated at a first piezoelectric temperature, and
the second piezoelectric effect is generated at a second piezoelectric temperature,
wherein the first piezoelectric temperature is different from the second piezoelectric temperature.

22. The method for generating electrical energy from temperature fluctuations of claim 19,
characterized in that
upon temperature fluctuations across a temperature interval, a plurality of bimetal lamellas (A, B, C, D, E1) is deformed at different temperatures as a result of the absorption or release of thermal energy.

23. An application of a device (1) for generating electrical energy from temperature fluctuations,
wherein the device (1) for generating electrical energy from temperature fluctuations has a first (A) and a second bimetal lamella (B),
wherein the two bimetal lamellas (A, B) each have an upper and a lower transition temperature,
wherein the upper transition temperatures of the two bimetal lamellas (A, B) and/or the upper transition temperatures of the two bimetal lamellas (A, B) are different.

24. The application of a device (1) for generating electrical energy from temperature fluctuations of claim 23,
characterized in that
the device (1) for generating electrical energy from temperature fluctuations has an array (100) of bimetal lamellas (A, B, C, D, E1),
wherein the electrical energy generated by the device (1) for generating electrical energy from temperature fluctuations is used as an energy supply in a network having off-grid components.

25. The application of a device (1) for generating electrical energy from temperature fluctuations of claim 23,
characterized in that
the array (100) has an array temperature interval where the device (1) for generating electrical energy from temperature fluctuations is suitable for converting thermal energy into electrical energy,
wherein the device (1) for generating electrical energy from temperature fluctuations is used in an environment having temperature fluctuations with a minimum and/or maximum temperature outside the array temperature interval.

26. The application of a device (1) for generating electrical energy from temperature fluctuations of claim 23,
characterized in that
the time intervals where the temperature fluctuations in the environment are outside the array temperature interval are greater than 24 hours, preferably 7 days and particularly preferably 28 days.
